(19) United States
(12) Patent Application Publication
(10) Pub. No.: US 2008/0258778 A1
(43) Pub. Date: Oct. 23, 2008

(54) CURRENT MIRROR CIRCUIT

(76) Inventor: Marco Schreiter, Dresden (DE)

Correspondence Address: Muncy, Geissler, Olds & Lowe, PLLC, P.O. BOX 1364, FAIRFAX, VA, 22038-1364, US

(21) Appl. No.: 11/944,600

(22) Filed: Nov. 23, 2007

Related U.S. Application Data
(60) Provisional application No. 60/860,793, filed on Nov. 24, 2006.

(30) Foreign Application Priority Data
Nov. 23, 2006 (DE) DE 102006055320

(51) Int. Cl. H03K 3/01

(52) U.S. Cl. 327/108

(57) ABSTRACT

The invention relates to a current mirror circuit (110) having a first transistor (112) and a second transistor (114), each of which have a control terminal (128, 136), formed particularly as a base or gate, and in each case two current terminals (124, 126, 132, 134), formed particularly as an emitter and collector or drain and source, whereby the control terminals (128, 136) of both transistors (112, 114) are connected to one another in an electrically conducting way at a connection node (140) and to a first current terminal (124, 126) of the first transistor (112) via a connecting line (150).

It is provided according to the invention that the connecting line (150) is assigned bias means, provided for shifting an electric potential at the first current terminal (124) of the first transistor (112) relative to an electric potential of the connection node (140).

Use in integrated circuits

This nonprovisional application claims priority to German Patent Application No. 102006055320, which was filed in Germany on Nov. 23, 2006, and to U.S. Provisional Application No. 60/860,793, which was filed on Nov. 24, 2006, and which are both herein incorporated by reference.

### FIELD OF THE INVENTION

The present invention relates to a current mirror circuit having a first transistor and a second transistor, each of which have a control terminal, formed particularly as a base or gate, and in each case two current terminals, formed particularly as an emitter and collector or drain and source, whereby the control terminals of both transistors are connected to one another in an electrically conductive way at a connection node and to a current terminal of the first transistor via a connecting line.

### DESCRIPTION OF THE BACKGROUND ART

This type of current mirror circuit is also called a simple current mirror circuit and is known from the prior art. The current mirror circuit can be used as a current-controlled current source and supplies at its output a copy of an input current; the copy of the input current, therefore the output current, can be the same, amplified, or reduced compared with the input current. The simple current mirror circuit is typically made with bipolar transistors or with field-effect transistors. An essential property of a current mirror circuit of this type is to assure a constant ratio of the input current and output current over a voltage range predefinable by the dimensioning of the transistors. Transistors, which are used typically for current mirror circuits and assure a substantially constant ratio of input voltage and output voltage, can be used only for voltages in the range of a few volts, because they are destroyed at higher voltages.

### SUMMARY OF THE INVENTION

The object of the present invention is to provide a current mirror circuit, which assures a substantially constant ratio of the input current and output current over an extended voltage interval.

Accordingly, a current mirror circuit is provided having a first transistor with a first current terminal, which is formed as a collector or drain and is supplied with a first current, having a second current terminal, formed as an emitter or source, and a second transistor with a current terminal, which is formed as a collector or drain and is supplied with a second current dependent on the first current, and a current terminal formed as an emitter or source, whereby the two transistors each have a control terminal formed as a base or gate and the control terminals are connected to one another in an electrically conductive manner at a connection node and the connection node is connected to the first current terminal of the first transistor via a connecting line, so that between the first current terminal and the connection node a bias means is provided, which by means of the current flowing through the bias means effects a shift of an electric potential of the first current terminal relative to an electric potential of the connection node.

The current mirror circuit of the invention of the aforementioned type is characterized in that the connecting line is assigned bias means, provided for shifting an electric potential at the first current terminal of the first transistor relative to an electric potential of the connection node. The bias means thus permit a change or correction of the electric potential applied between the current terminals of the first transistor to be able to compensate at least partially for the optionally nonlinear properties of transistors, designed for higher voltages. A predefinable, constant or variable, additional voltage is provided at the connection node between the two control terminals of the transistors preferably with the use of the bias means.

An embodiment of the invention provides that the bias means are formed in such a way that a shift of the electric potential at the first current terminal of the first transistor occurs in the direction of a pinch-off region of the transistor. In the pinch-off region or saturation region of transistors, a predefinable linear association between the input current at the first transistor and the output current at the second transistor is assured independent of the supply voltage applied at the second transistor between the current terminals. In a simple current mirror circuit, a short-circuit line between the control terminals and the first current terminal of the first transistor assures that an electric voltage between the two current terminals is the same as an electric voltage between the control terminal and the second current terminal of the first transistor. In a current mirror circuit, designed for higher electric voltages, additional resistance can occur between the current terminals due to the structure of the transistors. This resistance leads to an unwanted shift in the control voltage at the control terminals beyond the pinch-off or saturation region and therefore causes different currents at the second transistor at different voltages at the second transistor, which is undesirable. To assure, nevertheless, a constant input current/output current ratio over a broad voltage range, the aforementioned condition was modified by the bias means; in other words, the electric voltage between the current terminals of the first transistor is shifted by the bias means relative to the voltage at the control terminals in such a way that it is possible to operate the second transistor in the linear pinch-off or saturation region.

Another embodiment of the invention provides that the bias means comprise a diode which is looped electrically between the first current terminal of the first transistor and the connection node. The diode is used as a voltage source for the connection node between the control terminals insofar as a constant, current-independent electric voltage, which assures the desired shift in the electric potential at the connection node, drops at the diode when a threshold voltage is exceeded or a breakdown voltage occurs.

Another embodiment of the invention provides that the at least one diode is disposed in the forward direction based on an electric potential that can be applied between the connection node and the first current terminal. This assures that during application of an electric voltage at the diode, which corresponds at least to a threshold voltage of the diode, the desired electric additional voltage or offset voltage is provided at the connection node.

Another embodiment of the invention provides that the bias means comprise a series resistor, which is looped electrically between the connection node and a second current terminal of the first transistor. The series resistor is used to adjust the electric voltage applied at the diode and thereby to set the transmission properties of the diode.

Another embodiment of the invention provides that the series resistor has a resistance value that is at least 10, preferably at least 100, especially preferably at least 1000 times the value of a drain resistance of the first transistor. This assures that only a substantially negligible fraction of the electric current, provided by the current source assigned to the first transistor, flows across the series resistor and the diode and impresses a current there. A typical drain resistance value for a transistor that can carry a voltage of up to 80 V and has a channel width of 100 μm is about 1000 Ohm. The series resistor is greater at least by a factor of 10; a resistance value of the series resistor is preferably 1,000,000 Ohm.

Another embodiment of the invention provides that the diode is made as a Zener diode and has a breakdown voltage that is at least 1/20 of a maximum voltage of the first transistor. An offset voltage at the connection node relative to the voltage, which drops between the current terminals of the first transistor, can be predefined by using a Zener diode with a single electric component within a wide voltage range. Whereas a typical threshold voltage (forward voltage) of 0.6 V declines at a normal diode, the breakdown voltage of the Zener diode can be selected in a range from a few volts to two-digit volt values, so that individual adjustment to the transistor dimensioning can be assured. A typical breakdown voltage of a Zener diode provided in an integrated circuit is about 6.2 V.

It is provided in another embodiment of the invention that the transistors are made as double diffusion DMOS field-effect transistors for a maximum voltage greater than 50 V, preferably greater than 80 V. DMOS field-effect transistors of this type, due to the structure and dimensioning of a thickness of an n⁻-doped drift section, can be loaded with up to high voltages. Contrary to other integrated MOSFETs, in DMOS-FETs, in particular, a design of the p-doped bulk region can be provided not by a substrate, but by diffusion in an n⁻ substrate, so that a connection to a p⁺ contact region of the source is produced.

Other advantages and features of the invention arise from the claims and from the following description of a preferred exemplary embodiment. Whereas an explanation of a simple current mirror circuit according to the state of the art is provided first in FIG. 1, a novel exemplary embodiment of the invention is described with the use of FIG. 2.

### BRIEF DESCRIPTION OF THE DRAWINGS

The present invention will become more fully understood from the detailed description given hereinbelow and the accompanying drawings which are given by way of illustration only, and thus, are not limitive of the present invention, and wherein:

FIG. 1 shows a schematic drawing of a simple current mirror circuit according to the state of the art.

FIG. 2a shows a schematic drawing of an embodiment of a current mirror circuit according to the invention with two PMOS transistors, whose gate terminals are biased electrically with a series resistor and diodes.

FIG. 2b shows a schematic drawing of an embodiment of a current mirror circuit of the invention with two NMOS transistors, whose gate terminals are biased electrically with a series resistor and diodes.

FIG. 3 shows a schematic drawing of a characteristic of a known field-effect transistor according to FIG. 1 and a gate voltage for a current mirror circuit according to FIG. 2.

FIG. 4 shows a schematic drawing of a characteristic of a gate voltage for a known current mirror circuit with high-voltage field-effect transistors.

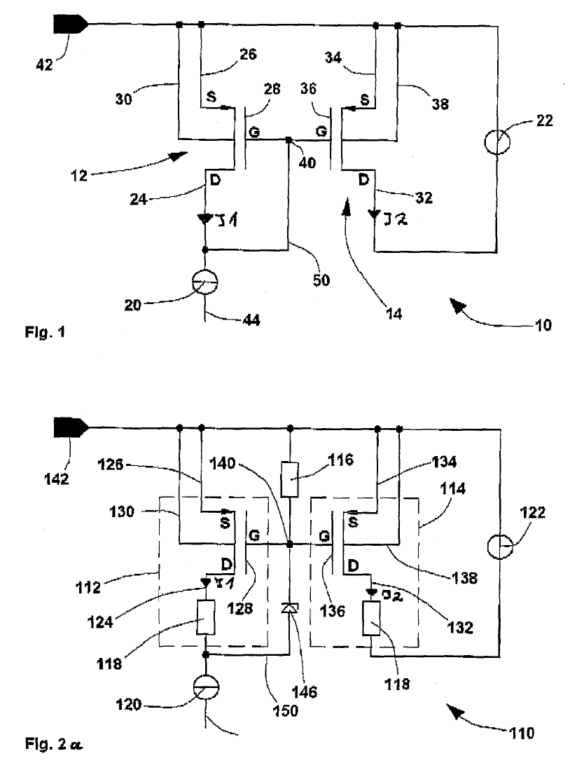

DETAILED DESCRIPTION FIG. 1 shows a prior-art, simple current mirror circuit 10 with a first PMOS transistor 12 and a second PMOS transistor 14. In this case, both control terminals, therefore gate terminal 28 and gate terminal 36 of transistors 12, 14, are connected to one another in an electrically conductive way at a connection node 40 and thus are at a common electric potential. To enable control of the two transistors 12, 14, an electric connection is provided between connection node 40 and one of the current terminals, in the present case drain terminal 24 of first transistor 12. Therefore, connection node 40 and gate terminals 28, 36 of transistors 12, 14 are at the electric potential of drain terminal 24 of first transistor 12. The condition USG1=USD1 can be formulated thereby; in other words, the gate-source voltage USG1 at first transistor 12 is the same as the source-drain voltage USD1 and this gate-source voltage USG1 is made available as the control voltage for gate 36 of second transistor 14.

Source terminals 26, 24 and bulk terminals 28, 36 of the two PMOS transistors 12 and 14 are at a common voltage potential of the supply voltage VDD, provided at supply terminal 42. In an embodiment, which is not shown, supply voltages that are different from one another can also be provided for the particular source and bulk terminals of the two transistors.

As soon as an externally impressed current I1 flows between source terminal 26 and drain terminal 24 of first transistor 12, a source-drain voltage USD1 becomes established and thereby also a gate-source voltage USG1. Because of condition USG1=USD1 forced by connecting line 50, for each impressed current I1 there is only precisely one operating point 54 for transistor 12, to which all boundary conditions apply. In other words, in the present case operating point 54 lies on characteristic 52 of transistor 12, said characteristic which is emphasized by way of example among a set of curves not shown in greater detail. It holds for exemplary operating point 54 (solely to clarify the aforementioned embodiment and by no means to be understood as limiting) that at an impressed current I1=2 mA the voltages USD1 and USG1 each settle at 3 V. As can be derived from characteristic 52 of transistor 12, operating point 54 already lies within the saturation or pinch-off region of transistors 12, 14, in which a change in the source-drain voltage USD does not cause a change in the current I2 and therefore, a constant ratio of input current I1 to output current I2 is assured. As a result, output current I2 releasable from second transistor 14 by means of gate-source voltage USG2 is virtually independent of the source-drain voltage USD2, provided by voltage source 22.

Therefore, over a broad interval of the source-drain voltage USD2 for second transistor 14, a constant ratio of the currents I1 to I2 can be assured and current mirror circuit 10 as desired has a linear relationship within the provided current interval.

Therefore, in a current mirror circuit with conventional transistors, designed for low electric voltages (e.g., up to 8 V), a constant ratio between current I1 through transistor 12 and current I2 through transistor 14 can be achieved without additional measures.

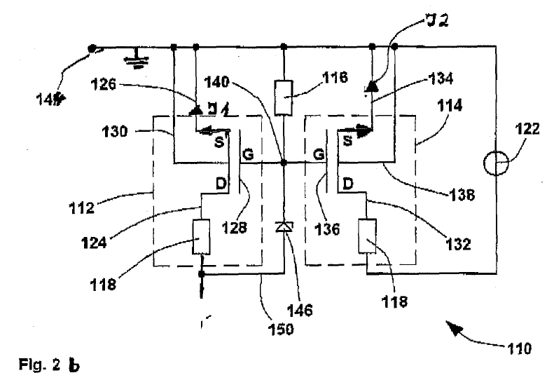

However, a different situation arises when high-voltage transistors are used, which are shown in FIG. 2 as transistors 112 and 114 and are made as DMOS field-effect transistors. Because of the need to assure a higher dielectric strength, for example, for voltages up to 100 V, high-voltage transistors have a different structure, not shown in greater detail. This different structure means that a drain resistance can no longer be disregarded. The first and second transistors 112, 114, shown as equivalent circuits, are made as high-voltage transistors and each have a drain resistor 118, depicted in each case as a discrete resistor for the sake of clarity. Characteristics 56, 58 can be produced for high-voltage transistors of this type, as they are shown in FIG. 4. Because of drain resistor 118, which cannot be disregarded, characteristics 56, 58 in addition have a pinch-off or saturation region displaced relative to normal transistors at higher source-drain voltages.

If a prior-art, simple current mirror circuit with transistors 112, 114 of this type is realized, a source-gate voltage of 4 V results because of the greater curvature of the characteristics 56, 58 at an exemplary current strength I1=2 mA and the still applicable condition USG1=USD1. It can be derived from characteristic 56 that, depending on the source-drain voltage applied at second transistor 114, output current I2 can deviate greatly from input current I1, because operations still occur in the curved region of characteristic 56, and therefore the current ratio I2/I1 is not constant, as is desired.

To be able to assure a constant current ratio I2/I1 for a current mirror circuit of this type also at low current strengths for I1, a Zener diode 146 is disposed in connecting line 150. Moreover, there is a series resistor 116, which is provided for electric coupling of connection node 140 with the supply voltage VDD and assures a minimum current for switching through Zener diode 146.

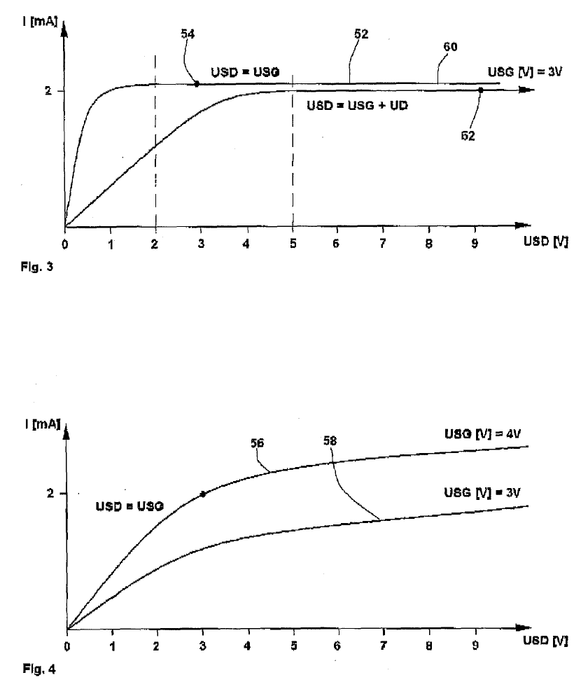

Zener diode 146 is disposed in the blocking direction relative to the supply voltage VDD, so that only when a source-drain voltage greater than the breakdown voltage UD of Zener diode 146 is exceeded, a potential is applied to gates 128 and 136 of transistors 112 and 114 via connecting line 150. Provided that the breakdown voltage UD of Zener diode 146 is exceeded and a potential is applied at connection node 140, Zener diode 146 acts like a voltage source and provides a current-independent constant additional voltage at connection node 140; here, the additional voltage corresponds to the breakdown voltage UD of Zener diode 146. As an example, a Zener diode 146 with a breakdown voltage of UD=6 V is assumed, so that the source-drain voltage USD1 at a gate-source voltage of 3 V is increased by the breakdown voltage UD=6 V and thus is 9 V. As a result, the operating point of the current mirror circuit is displaced and occurs in the pinch-off or saturation region even at low gate-source voltages USG, as is shown in FIG. 3 in characteristic 60. Providing the offset voltage by Zener diode 146 for current mirror circuit 110 according to the exemplary embodiment in FIG. 2 results in the characteristic 60 shown in FIG. 3, in which it can be seen that operating point 62 satisfies the condition USD=USG+UD and, therefore, with high currents a constant ratio of the input current I1 and output current I2 can also be assured.

In an embodiment of the invention shown in FIG. 2b, NMOS field-effect transistors are used instead of PMOS field-effect transistors; in this case, a lower potential shift is effected with the aid of the bias means because of the somewhat lower drain resistance. In this case, the source of the NMOS transistors are connected to the reference potential or ground potential, whereas at least one bias means, preferably a resistor, is looped at the drain of the first transistor to shift the potential of the drain relative to the control terminals of the two transistors. This type of circuit is shown in FIG. 3. Here, the same reference characters designate the same terminals.

The invention being thus described, it will be obvious that the same may be varied in many ways. Such variations are not to be regarded as a departure from the spirit and scope of the invention, and all such modifications as would be obvious to one skilled in the art are to be included within the scope of the following claims.

1. A current mirror circuit comprising:
a first transistor with a first current terminal, which is formed as a collector or drain and is supplied with a first current;
a second current terminal, formed as an emitter or source;
a second transistor with a current terminal, which is formed as a collector or drain and is supplied with a second current dependent on the first current; and
a current terminal, formed as an emitter or source,
wherein the two transistors each have a control terminal formed as a base or gate and the control terminals are connected to one another in an electrically conductive manner at a connection node and the connection node is connected to the first current terminal of the first transistor via a connecting line, and
wherein between the first current terminal and the connection node a bias is provided, which by means of the current flowing through the bias effects a shift of an electric potential of the first current terminal relative to an electric potential of the connection node.

2. The current mirror circuit according to claim 1, wherein the bias are formed in such a way that a shift of the electric potential at the first current terminal of the first transistor occurs in the direction of a pinch-off region of the transistor.

3. The current mirror circuit according to claim 1, wherein the bias comprises a diode which is looped electrically between the first current terminal of the first transistor and the connection node.

4. The current mirror circuit according to claim 3, wherein the at least one diode is disposed in the forward direction based on an electric potential that can be applied between the connection node and the first current terminal.

5. The current mirror circuit according to claim 3, wherein the bias comprise a series resistor, which is looped electrically between the connection node and a second current terminal of the first transistor.

6. The current mirror circuit according to claim 5, wherein the series resistor has a resistance value that is at least 10, preferably at least 100, especially preferably at least 1000 times the value of a drain resistance of the first transistor.

7. The current mirror circuit according to claim 1, wherein the diode is made as a Zener diode and has a breakdown voltage that is at least 1/20 of a maximum voltage of the first transistor.

8. The current mirror circuit according to claim 1, wherein the transistors are made as double diffusion DMOS field-effect transistors for a maximum voltage greater than 50 V, preferably greater than 80 V.
